(19) United States
(12) Patent Application Publication
(10) Pub. No.: US 2005/0116322 A1
(43) Pub. Date: Jun. 2, 2005

(54) Circuit module

(76) Inventors: Fumio Sando, Tochigi (JP); Yusuke Igarashi, Gunma (JP); Noriaki Sakamoto, Gunma (JP)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 10/900,524

(22) Filed: Jul. 28, 2004

(30) Foreign Application Priority Data
Jul. 31, 2003 (JP) P. 2003-204297
Jul. 13, 2004 (JP) P. 2004-205793

(51) Int. Cl. H01L 23/29; H01L 23/48

(52) U.S. Cl. 257/676; 257/692; 257/787

(57) ABSTRACT

A circuit module of the present invention has leads serving as terminals for performing electrical input from, and output to exterior, a circuit device in which a first circuit element electrically connected to at least one of the leads is sealed with first sealing resin, a second circuit element fixed to an island formed in one of the leads, and second sealing resin for sealing the circuit device and the second circuit element. Here, the circuit device has a conductive pattern with an interval smaller than that between the leads.

### BACKGROUND OF THE INVENTION

Priority is claimed to Japanese Patent Application Serial No. JP2003-204297, filed on Jul. 31, 2003, and JP2004-205793, filed on Jul. 13, 2004, the disclosures of which are incorporated herein by reference in its entireties.

1. Field of the Invention

The present invention relates to a circuit module. In particular, the present invention relates to a circuit module having leads as external terminals.

2. Description of the Related Arts

With reference to FIG. 9A and FIG. 9B, the structure of a conventional-type circuit device 100 will be described. FIG. 9A is a plan view of the circuit device 100, and FIG. 9B is a cross-sectional view thereof.

A land 102 made of conductive material is formed in the center of the circuit device 100, and one ends of a large number of leads 101 are close to the periphery of the land 102. The one ends of the leads 101 are electrically connected to a semiconductor element 104 through fine metal wires 105, and the other ends are exposed from sealing resin 103. The sealing resin 103 has the function of sealing the semiconductor element 104, the land 102, and the leads 101 and supporting them as one entity.

Moreover, in the case where the semiconductor element 104 is a high-power element, the leads 101 are formed thickly in order to efficiently release heat generated by the semiconductor element 104 to the outside and in order to ensure a current capacity.

On the other hand, a thin-type package called SIP (System-In-Package) is recently developed. In this SIP, generally, a flexible sheet or the like is used as a base substrate, some elements are mounted thereon, and the entirety is molded. Moreover, a large number of external connection electrodes are formed on the back surface of this package, and solder balls are fixed to the external connection electrodes.

However, a leadframe-type package has the problem that active elements, such as an LSI and/or TRs, and passive elements, such as chip capacitors, cannot be simultaneously incorporated therein. This is because it is difficult to electrically connect these elements using a leadframe.

On the other hand, in an SIP-type package, it is possible to incorporate active elements, such as an LSI and/or TRs, and passive elements, such as chip capacitors, into one package. However, since the SIP-type package is thin and small, solder balls are small. This causes the problem that, when the SIP is mounted on a printed-circuit board or the like, cracks occur in the solder balls due to the difference in thermal expansion coefficients between the mount board and the package. Further, when the SIP is realized as a high-performance semiconductor element in an atmosphere in which heat is produced, e.g., an on-vehicle environment or the like, problems occur in terms of heat dissipation and electrical connection.

Furthermore, in the circuit device 100 as described above, the individual leads 101 are formed thickly by machining a thick metal substrate. Accordingly, in the case where leads 101 having thicknesses of approximately 0.5 mm are formed, the interval between the leads 101 also becomes 0.5 mm or more. This causes the problem that a complex electrical circuit cannot be constructed inside the circuit device using the leads 101.

### SUMMARY OF THE INVENTION

The preferred embodiments of the present invention have been accomplished in light of the above-described problems. A major object of the preferred embodiments of the present invention is to provide a circuit module having leads and, inside, a fine pattern. Moreover, another object of the preferred embodiments of the present invention is to provide a circuit module in which the mechanical stress of a mount board is absorbed by adopting a leadframe and in which a high-performance system is incorporated.

A circuit module of the preferred embodiments comprises: leads serving as terminals for performing electrical input from, and output to, exterior; a circuit device in which a first circuit element electrically connected to at least one of the leads is sealed with first sealing resin; a second circuit element fixed to an island attached to one of the leads; and second sealing resin for sealing the circuit device and the second circuit element. Here, the circuit device has a conductive pattern with an interval smaller than that between the leads.

Further, a circuit module of the preferred embodiments comprises: leads serving as terminals for performing electrical input from, and output to, exterior; a mount board on which a first circuit element electrically connected to at least one of the leads is mounted; a second circuit element fixed to an island attached to one of the leads; and sealing resin for sealing the mount board and the first and second circuit elements. Here, the mount board has a conductive pattern with an interval smaller than that between the leads.

Furthermore, a circuit module of the preferred embodiments comprises: a circuit device in which a circuit element is sealed with first sealing resin; second sealing resin for sealing the circuit device; and leads electrically connected to the circuit device and led from the second sealing resin to exterior. Here, a thermal expansion coefficient of the second sealing resin is larger than that of the first sealing resin.

### BRIEF DESCRIPTION OF THE DRAWINGS

FIG. 1A is a plan view, FIG. 1B is a cross-sectional view, and FIG. 1C is cross-sectional view showing a circuit module of some preferred embodiments.

FIG. 2A to FIG. 2D are cross-sectional views showing a circuit module of the preferred embodiments.

FIG. 3A is a plan view and FIG. 3B is a cross-sectional view showing a circuit module of the preferred embodiments.

FIG. 4A to FIG. 4D are cross-sectional views showing a circuit module of the preferred embodiments.

FIG. 5 is a cross-sectional view showing a circuit module of the preferred embodiments.

FIG. 6 is a plan view showing a circuit module of the preferred embodiments.

FIG. 7A is a plan view and FIG. 7B is a cross-sectional view showing a circuit module of the preferred embodiments.

FIG. 8A to FIG. 8C are cross-sectional views showing a circuit module of the preferred embodiment.

FIG. 9A is a plan view and FIG. 9B is a cross-sectional view showing a conventional circuit device.

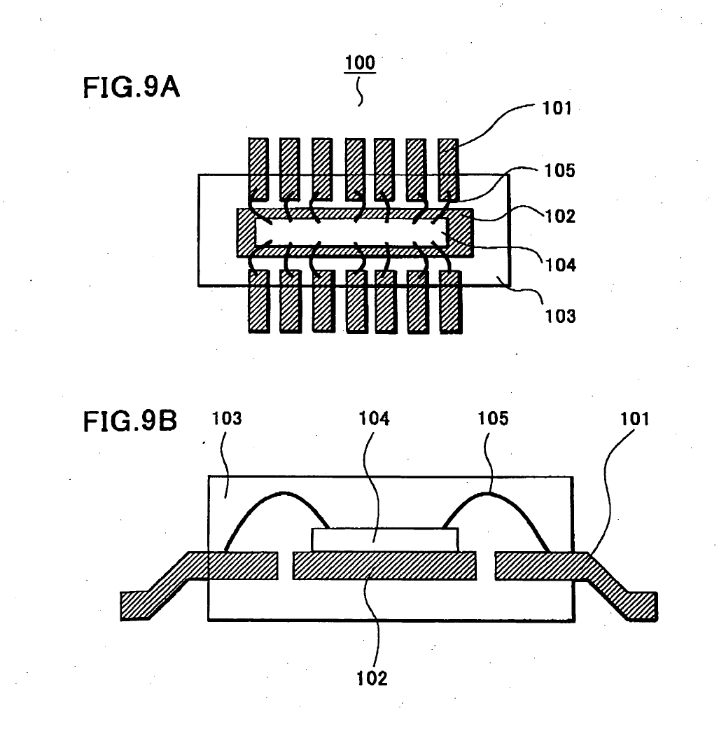

### DESCRIPTION OF THE PREFERRED EMBODIMENTS

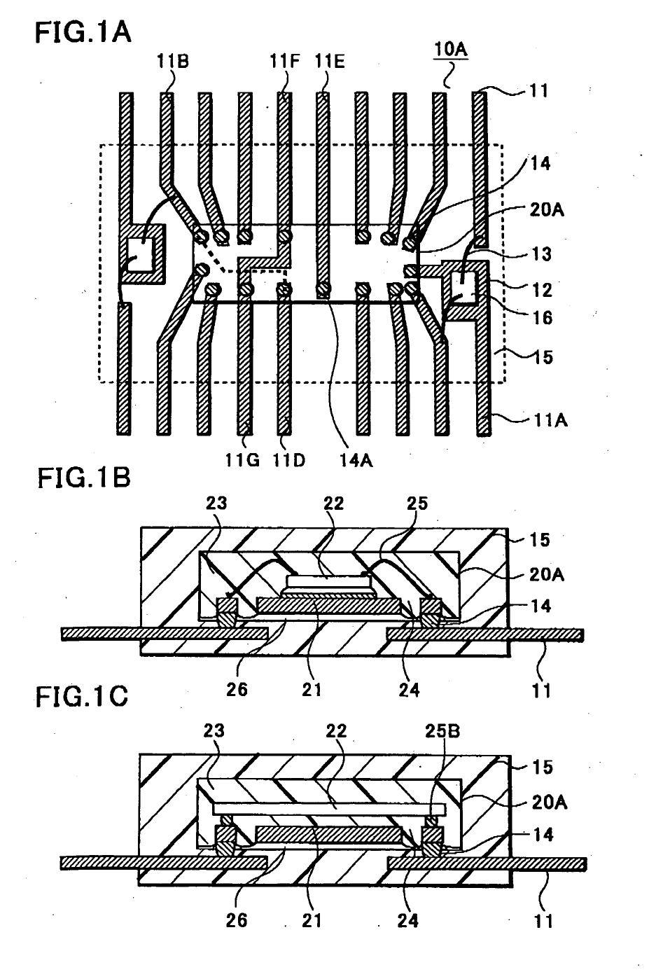

The structure of a circuit module 10A of the preferred embodiments of the present invention will be described with reference to FIG. 1A and FIG. 1B. FIG. 1A is a plan view of the circuit module 10A, and FIG. 1B is a cross-sectional view thereof.

As can be seen from these drawings, the circuit module 10A of a preferred embodiment has a structure in which a thin-type circuit device, such as a SIP, provided with external connection electrodes is mounted on a leadframe and sealed with resin. This structure allows a large number of elements to be simultaneously incorporated therein and makes it possible to realize a module in which leads are adopted with a circuit device in which external electrodes can only be provided on the back surface thereof. Even when the circuit module 10A is mounted on a printed-circuit board, a ceramic board, or a metal board (hereinafter referred to as a mount board), thermal stress is reduced by the leads 11, and furthermore, heat release properties can also be improved.

In the circuit module 10A, a circuit device 20A is mounted on leads 11. Further, a high-power semiconductor element (power MOS, IGBT, or power IC) is mounted as a bare chip on an island 12 separately of the circuit device 20A.

For example, suppose that six switching transistors of inverters and a driving circuit for driving these switching transistors are incorporated into the circuit module 10A. In this case, the six transistors are mounted on islands 12 in this case. Further, the complex driving circuit including a plurality of elements is packaged as the circuit device 20A. This structure allows a complex, high-performance circuit, which cannot be realized with only a leadframe, to be realized as the circuit device 20A, and elements requiring heat release can release heat by adopting leads. In addition, even when the circuit module 10A is mounted on a mount board, a decrease in reliability, such as bad connection, does not occur because the circuit device 20A is electrically connected to leads.

Specifically, there is a circuit device 20A having connection portions 14 formed on the back surface thereof. Further, a plurality of leads 11 are provided in a region corresponding to the back surface of the circuit device 20A. Moreover, an island 12 is provided for a second circuit element 16 requiring heat dissipation. Furthermore, a lead 11 is also provided in the vicinity of the island 12. Here, the island 12 is integral with the lead 11, and also functions as a ground lead.

The leads 11, one ends of which are led from the second sealing resin 15 to the outside, function as terminals for performing electrical input from, and output to, the outside. The other ends of leads 11 are electrically connected to the elements incorporated in the circuit module. Moreover, in order to actively emit heat generated by the elements incorporated in the module, and further, in order to ensure a large current capacity, the cross sections of the leads 11 are formed into large thickness. For example, when the cross section of each lead 11 is set to approximately 0.5 mm×0.5 mm, it is possible to sufficiently ensure a current capacity and sufficiently improve heat release properties. Further, the leads 11 are formed by machining a thick metal substrate. Machining methods for this include punching using a die and etching. This makes it difficult to make the interval between the leads 11 significantly narrower than the thicknesses thereof. In practice, the interval between the leads 11 is made approximately equal to the thicknesses thereof (e.g., 0.5 mm or more). As a material for the leads 11, copper, iron, nickel, aluminum, or alloys thereof can be generally adopted. In this example, the leads 11 are led to the outside from opposite sides of the module. However, the leads 11 can also be led to the outside in four directions or one direction.

Furthermore, the leads 11 can be extended under the circuit device 20A. Specifically, referring to FIG. 1A, one end of the lead 11E is led to the outside from the upper side of the second sealing resin 15 in this drawing. Meanwhile, the other end of the lead 11E is extended under the circuit device 20A to be connected to a connection portion 14A formed in the peripheral portion of the circuit device 20A which is opposite (the lower in this drawing) from the direction in which the lead 11E is led to the outside.

Moreover, referring to FIG. 1A, the leads 11F and 11G are led to the outside from the opposite sides of the circuit module 10A, but coupled together under the circuit device 20A. Thus, the flexibility of wiring design of the leads 11 can be improved by extending leads 11 under the circuit device 20A.

The connection portions 14 are made of brazing material, such as solder, and have the function of mechanically and electrically connecting the circuit device 20A and leads 11. Further, as a material for the connection portions 14, conductive paste, such as Ag paste or Cu paste, can also be adopted. The circuit device 20A can be mounted on leads 11 by a reflow step in which the connection portions 14 formed on the back surface of the circuit device 20A are melted. Specifically, the circuit device 20A and leads 11 can be joined together by applying flux to the surfaces of the areas of the leads 11 with which the connection portions 14 come into contact, placing the circuit device 20A on a desired position and performing reflow soldering.

The second sealing resin 15 covers the leads 11, the circuit device 20A, the second circuit element 16, and fine metal wires 13. Further, the leads 11 are led to the outside from the second sealing resin 15 to function as terminals for performing electrical input from, and output to, the outside.

The circuit device 20A is incorporated in the circuit module 10A, and mechanically and electrically connected to leads 11 through the connection portions 14 made of brazing material such as solder. The circuit device 20A has a shape in which the support substrate is eliminated, and is a thin-type package. Here, the circuit device 20A is primarily composed of the conductive pattern 21, the first circuit element 22 mounted on the conductive pattern 21, the first sealing resin 23 sealing the first circuit element 22 with the back surface of the conductive pattern 21 exposed. A semiconductor element, which is an LSI chip, is employed as the first circuit element 22 here. The first circuit element 22 and the conductive pattern 21 are electrically connected through fine metal wires 25. Accordingly, the first circuit element 22 is electrically connected to leads 11 through the fine metal wires 25, the conductive pattern 21, and the connection portions 14.

For the conductive pattern 21, the same materials as the aforementioned metals capable of being used for the leads 11 can be adopted. In this example, the conductive pattern 21 forms a die pad on which the first circuit element 22 as a semiconductor element is mounted, and bonding pads to which the fine metal wires 25 are bonded. Moreover, a wiring portion for constructing desired circuits inside the circuit device 20A may be formed by the conductive pattern 21. Further, the connection portions 14 for connecting to leads 11 are formed on the back surface of the conductive pattern 21. Here, the interval of the conductive pattern 21 is, for example, approximately 150 μm, and a fine pattern with a smaller interval can also be formed.

The back surface of the circuit device 20A, except for the areas where the connection portions 14 are formed, is covered with resist 26. Accordingly, using this resist 26, the two-dimensional sizes of the connection portions 14 made of brazing material such as solder can be regulated. Furthermore, the back surface of the conductive pattern 21 and the leads 11 can be electrically isolated by the resist 26.

The second circuit element 16 is fixed to the island formed in the lead 11A. As described previously, the lead 11A is formed thickly. Accordingly, even in the case where a high-power semiconductor element is adopted as the second circuit element 16, a large current can be dealt with, and furthermore, heat generated by the second circuit element 16 can be released to the outside. Moreover, as the second circuit element 16, elements other than semiconductor elements can also be adopted. Other than chip resistors and chip capacitors, passive elements and active elements can also be generally adopted. The back surface of the second circuit element 16 is fixed to the island, and electrodes formed on the front surface of the second circuit element 16 and other leads 11 are connected through the fine metal wires 13.

Furthermore, though the island 12 and the lead 11A are coupled together in FIG. 1A, the island 12 may be formed in the state where the island 12 is separated from the lead 11A. This allows the back surface of the second circuit element 16 fixed to the island 12 to be made independent from the leads 11.

In addition, an element which generates a larger amount of heat than the first circuit element 22 incorporated in the circuit device 20A, is adopted as the second circuit element 16. For example, a high-power semiconductor element may be adopted as the second circuit element 16 while an LSI chip for controlling the second circuit element is adopted as the first circuit element 22.

A point of this preferred embodiment of the present invention is that the circuit device 20A in which external connection electrodes exist on the back surface of an SIP-type package is mounted on the leadframe 11. This prevents the circuit device 20A from being fixed directly to a mount board. Accordingly, it is possible to prevent a decrease in reliability, such as a solder crack due to the thermal expansion of the mount board. Moreover, the second circuit element 16, which is a high-power element, is fixed to the island 12 continuous with the leadframe 11 and sealed with the second sealing resin 15. As a result, heat generated by the second circuit element 16 can be favorably released. Further, a complex conductive pattern which cannot be realized with a leadframe can be realized in the circuit device 20A.

In addition, in the case where the circuit device 20A is fixed to leads 11 with the connection portions 14, which are brazing material, the connection portions 14 are surrounded by the second sealing resin 15. The second sealing resin 15 is sealed, for example, at high heat, and therefore continues exerting compressive force on the connection portions 14. This also has the effect of preventing cracks in the connection portions 14.

Furthermore, another point of this preferred embodiment is that the interval of the conductive pattern 21 inside the circuit device 20A is narrower than that between the leads 11. Specifically, the leads 11 are formed thickly, but the conductive pattern 21 is formed into fine size. That is, a current capacity is ensured and heat release properties are improved by forming the leads 11 to be thick. Further, forming the conductive pattern 21 to be fine makes it possible to route a pattern for constituting a complex electric circuit and to realize crossed wiring. Moreover, it is also possible to incorporate a wiring portion for connecting leads 11 between themselves into the circuit device 20A. For example, referring to FIG. 1A, a wiring portion for electrically connecting the leads 11B and 11D can be formed along the path of the dotted line shown in this drawing.

In addition, referring to FIG. 1C, the first circuit element 22 is flip-chip mounted in the circuit device 20A here. That is, the first circuit element 22 is electrically connected to the conductive pattern 21 through bump electrodes 25B.

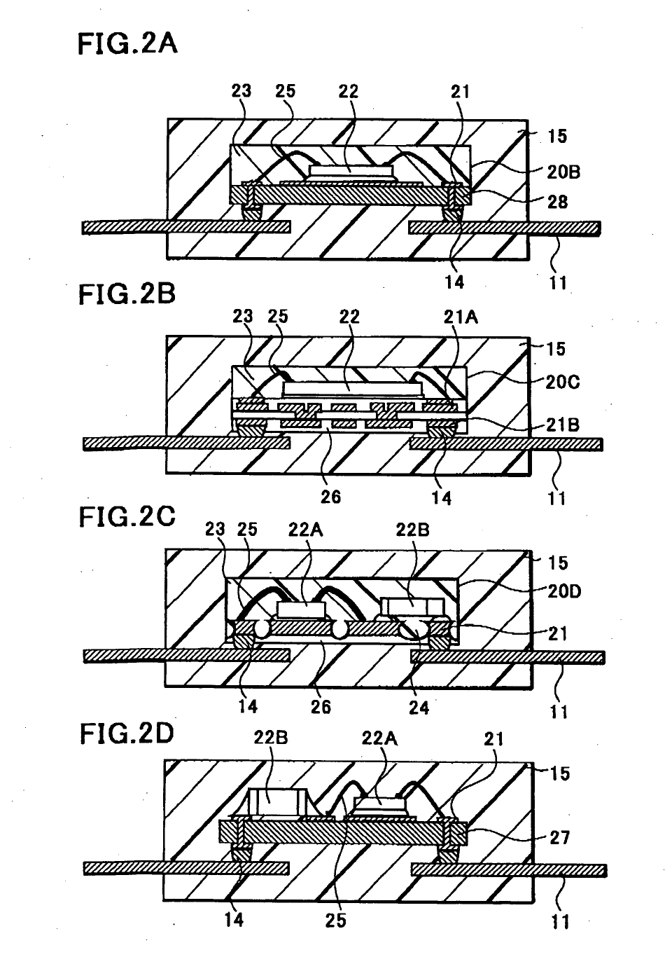

With reference to FIG. 2A to FIG. 2D, structures of the circuit module 10A of other embodiments will be described. FIG. 2A to FIG. 2D are cross-sectional views for explaining the respective structures of the circuit module 10A of the embodiments. The basic structures of these circuit modules are the same as those described with reference to FIG. 1A to FIG. 1C. Accordingly, the following description will center on differences.

Referring to FIG. 2A, a circuit device 20B has a support substrate 28 here. Specifically, the conductive pattern 21 is formed on the front surface of the support substrate 28, and the first circuit element 22 electrically connected to the conductive pattern 21 is covered with the first sealing resin 23. Further, the conductive pattern 21 is also extended to the back surface of the support substrate 28 and electrically connected to leads 11 through the connection portions 14. For the support substrate 28, a substrate made of resin, a substrate made of ceramic, and the like can be generally adopted.

Referring to FIG. 2B, a circuit device 20C has a multilayer wiring structure including first and second conductive patterns 21A and 21B. The first and second conductive patterns 21A and 21B are laminated with an insulating layer interposed therebetween, and connected at desired positions in such a manner that the insulating layer is penetrated. The first conductive pattern 21A is connected to the first circuit element 22 thorough the fine metal wires 25, and the second conductive pattern 21B is fixed to leads 11 through the connection portions 14. In particular, for the first conductive pattern 21A, a fine pattern can be formed because the interval of the conductive pattern 21A can be set to approximately 50 μm.

Referring to FIG. 2C, a semiconductor element 22A and a chip element 22B are adopted as first circuit elements 22 here. Specifically, a plurality of elements can be incorporated into a circuit device 20D, and active elements and passive elements can be generally adopted as the incorporated elements. Transistors, diodes, an IC chip, and/or the like are adopted as active elements. Further, chip resistors, chip capacitors, or the like are adopted as passive elements. Furthermore, an SIP (System-In-Package) in which a system is constituted by a plurality of electrically connected first circuit elements 22, can be adopted as the circuit device 20D.

Moreover, in the case where a plurality of elements are incorporated into the circuit module 10A, an element in which a large current flows can also be fixed as the second circuit element 16 on the island 12 of the lead 11A while the other element as the first circuit element 22 is incorporated into the circuit device 20A.

Referring to FIG. 2D, the basic structure of the circuit module shown in this drawing is the same as those shown in FIG. 1A to FIG. 1C, but differs in that the semiconductor element 22A and the chip element 22B as first circuit elements 22 are mounted on the mount board 27.

Specifically, the semiconductor element 22A and the chip element 22B as first circuit elements 22 are fixed on the fine conductive pattern 21 formed on the front surface of the mount board 27. Further, the conductive pattern 21 is extended to the back surface of the mount board 27 in such a manner that the mount board 27 is penetrated. The conductive pattern 21 is electrically connected to leads 11 by means of the connection portions 14. Accordingly, the mount board 27 on which the first circuit elements 22 are mounted is an equivalent of the circuit device 20A shown in FIG. 1A to FIG. 1C. For the mount board 27, a substrate made of resin, a substrate made of ceramic, and the like can be generally adopted. Moreover, a multilayer wiring structure may be formed inside the mount board 27.

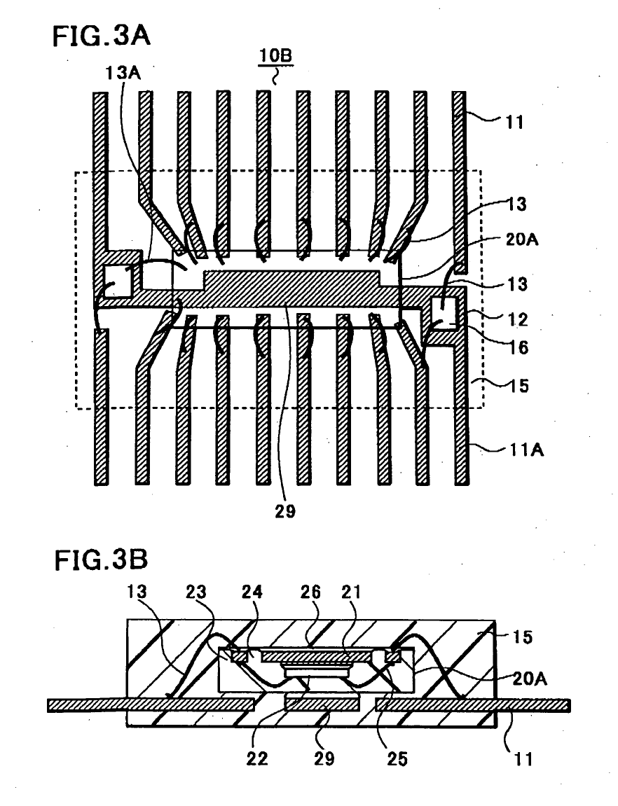

With reference to FIG. 3A and FIG. 3B, the structure of a circuit module 10B of another embodiment will be described. FIG. 3A is a plan view of the circuit module 10B, and FIG. 3B is a cross-sectional view thereof.

Referring to FIG. 3A and FIG. 3B, the circuit device 20A is incorporated in the circuit module 10B in the state where the surface thereof on which the back surface of the conductive pattern 21 is exposed is faced up. Further, the back surface of the conductive pattern 21 and leads 11 are electrically connected through the fine metal wires 13. Moreover, the circuit device 20A is fixed to a land 29 by means of an adhesive agent or the like. The size of the land 29 may be larger than or smaller than that of the circuit device 20A.

In the case where aluminum is adopted as a material for the fine metal wires 13, wire bonding can be directly performed without forming plated films on the back surface of the conductive pattern 21 and the front surfaces of the leads 11. This allows the simplification of the manufacturing process and the structure.

Moreover, referring to FIG. 3A, the back surface of the conductive pattern 21 of the circuit device 20A and the second circuit element 16 are electrically connected by the fine metal wire 13A. This structure allows the circuit device 20A and the second circuit element 16 to be directly connected.

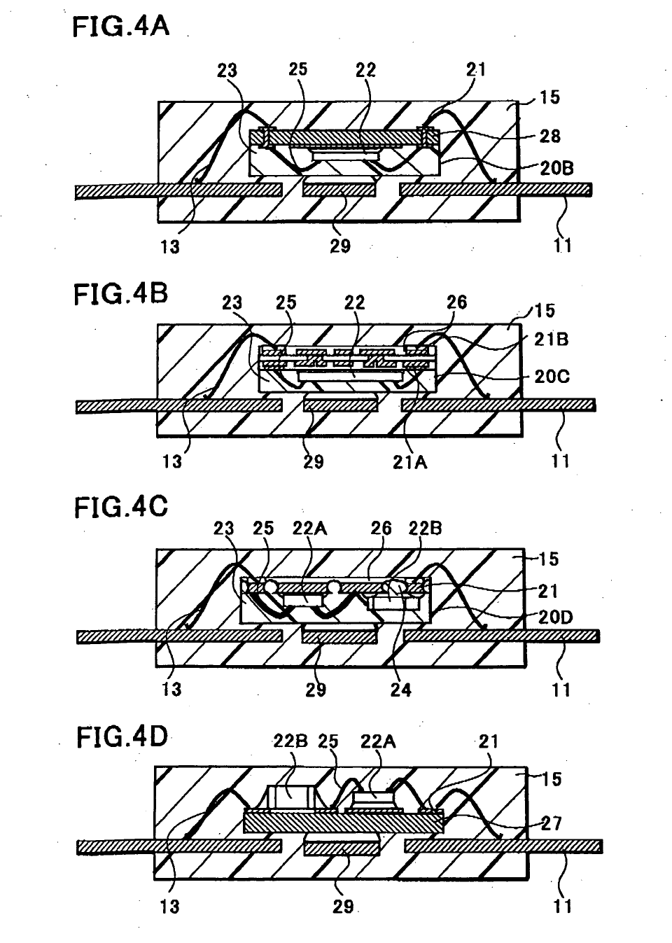

With reference to FIG. 4A to FIG. 4D, structures of the circuit module 10B of other embodiments will be described. FIG. 4A to FIG. 4D are cross-sectional views for explaining the respective structures of the circuit module 10B of the embodiments. The basic structures of these circuit modules are the same as that described with reference to FIG. 3A and FIG. 3B.

Referring to FIG. 4A, the circuit device 20B having the support substrate 28 is incorporated in the circuit module 10B here. Further, the conductive pattern 21 on the back surface (top surface here) of the support substrate 28 and leads 11 are electrically connected by the fine metal wires 13.

Referring to FIG. 4B, the circuit device 20C having a multilayer wiring structure which includes the first and second conductive patterns 21A and 21B is incorporated in the circuit module 10B. The second conductive pattern 21B exposed on the top surface of the circuit device 20C and leads 11 are electrically connected by the fine metal wires 13.

Referring to FIG. 4C, a plurality of first circuit elements 22 are incorporated in the circuit device 20D. The semiconductor element 22A and the chip element 22B are incorporated therein here.

Referring to FIG. 4D, the semiconductor element 22A and the chip element 22B as first circuit elements 22 are fixed to the conductive pattern 21 formed on the front surface of a mount board 27. Further, leads 11 and conductive pattern 21 which are in the peripheral portion of the mount board 27 are electrically connected through the fine metal wires 13.

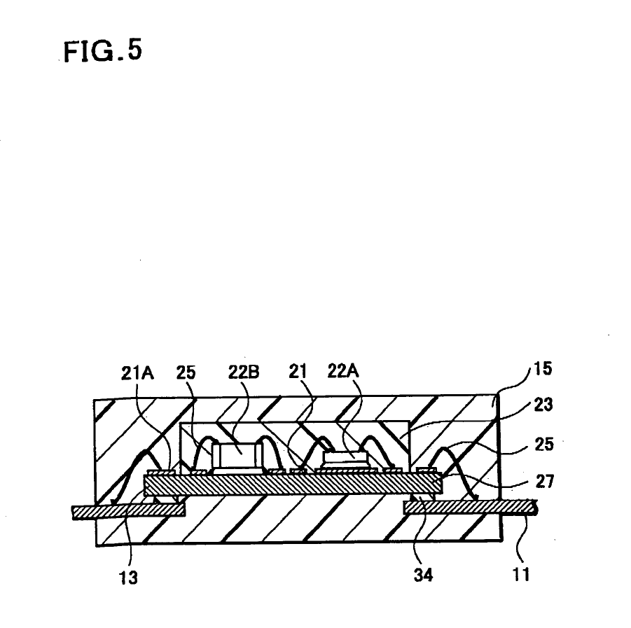

With reference to the cross-sectional view of FIG. 5, the structure of a circuit module of other embodiments will be described.

In the circuit module shown in this drawing, a circuit element is mounted on the front surface of the mount board 27, and the mount board 27 and leads 11 are connected through fine metal wires 25. Moreover, the chip element 22B mounted on the mount board 27 is also connected to the conductive pattern 21 by fine metal wires 25. That is, electrical connection is performed by use of the fine metal wires 25 only. Accordingly, since a brazing material and a conductive adhesive agent are eliminated, connection reliability is improved.

Specifically, pads 21A made of the conductive pattern 21 are formed in the peripheral portion of the mount board 27. Further, the pads 21A and leads 11 are electrically connected through fine metal wires 25. The first sealing resin 23 for sealing the circuit element is formed on the front surface of the mount board 27. Here, the first sealing resin 23 is formed with the exception of the peripheral portion of the mount board 27 in which the pads 21A are formed. Moreover, the mount board 27 and leads 11 are mechanically fixed by use of an adhesive agent 34.

In general, the chip element 22B is connected to the conductive pattern 21 through brazing material, but, in this example, connected thereto by use of fine metal wires 25. Specifically, the fine metal wires 25 are connected to the top surfaces of electrode portions located at both ends of the chip element 22B. Accordingly, gold plating for wire bonding may be performed on the top surfaces of the electrode portions of the chip element 22B. Moreover, the chip element 22B is fixed to the front surface of the mount board 27 by use of an insulating adhesive agent.

In the case where the chip element 22B is, for example, a chip capacitor, the thermal expansion coefficient thereof is 10×10⁻⁶/° C., and the value thereof is small compared to that of the mount board. Consequently, in the case where the chip element 22B is fixed to the mount board 27 by use of brazing material, there has been the problem that cracks occur in the brazing material. In the present embodiment, since the brazing material is omitted, connection reliability is improved.

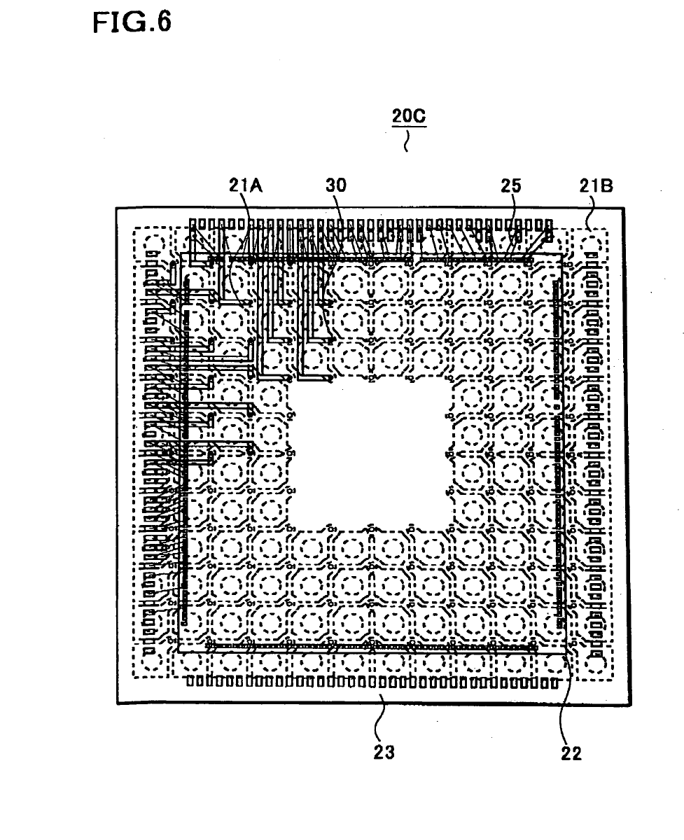

One example of a specific wiring structure of the conductive pattern 21 which a circuit device 20 has will be described with reference to FIG. 6. The wiring structure of the circuit device 20C having a multilayer wiring structure will be described here.

Referring to this drawing, the first conductive pattern 21A electrically connected to the fine metal wires 25 is represented by solid lines, and the second conductive pattern 21B laminated below the first conductive pattern with an insulating layer is represented by dotted lines.

The first conductive pattern 21A forms bonding pad in a peripheral portion of the first circuit element 22 incorporated in the circuit device 20C, and electrically connected to the first circuit element 22 through the fine metal wires 25. Moreover, the interval of the first conductive pattern 21A is approximately 50 μm. A very fine pattern can be formed. The first conductive pattern 21A here forms the bonding pad in the peripheral portion and is extended to multilayer connection portions 30. Further, the multilayer connection portions 30 penetrate the insulating layer to electrically connect the first and second conductive patterns 21A and 21B.

The second conductive pattern 21B mainly forms external electrodes. Specifically, in the case of a connection structure as shown in FIG. 1A to FIG. 1C, the second conductive pattern 21B becomes places in which the connection portions 14 made of brazing material are formed. Meanwhile, in the case of a connection structure as shown in FIG. 3A and FIG. 3B, the second conductive pattern 21B becomes places to which the fine metal wires 13 are bonded. Moreover, a wiring portion for connecting leads 11 can also be formed by the second conductive pattern 21B. Furthermore, a wiring portion for crossing interconnections can also be formed by the second conductive pattern 21B inside the circuit device 20C.

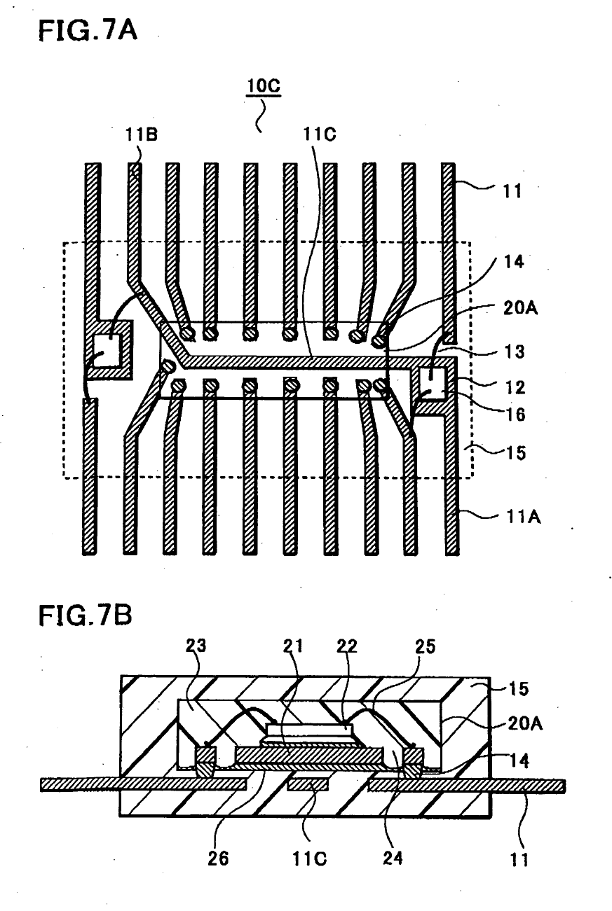

Next, the circuit module 10C of another embodiment will be described with reference to FIG. 7A and FIG. 7B. FIG. 7A is a plan view of the circuit module 10C, and FIG. 7B is a cross-sectional view thereof.

Referring to FIG. 7A, the plurality of leads 11 are provided on opposite sides of the circuit module 10C. Further, the circuit device 20A is fixed face-down to leads 11 through the connection portions 14. The leads 11A and 11B are connected by a wiring portion 11C extended under the circuit device 20A.

Referring to FIG. 7B, as described above, the wiring portion 11C is extended under the circuit device 20A. Further, in the circuit device 20A, the back surface of the conductive pattern 21 is exposed from the first sealing resin 23. However, the conductive pattern 21 is covered with resist 26 except the areas in which the connection portions 14 are formed Accordingly, the resist 26 makes it possible to prevent the conductive pattern 21 of the circuit device and the wiring portion 11C from coming into contact with each other.

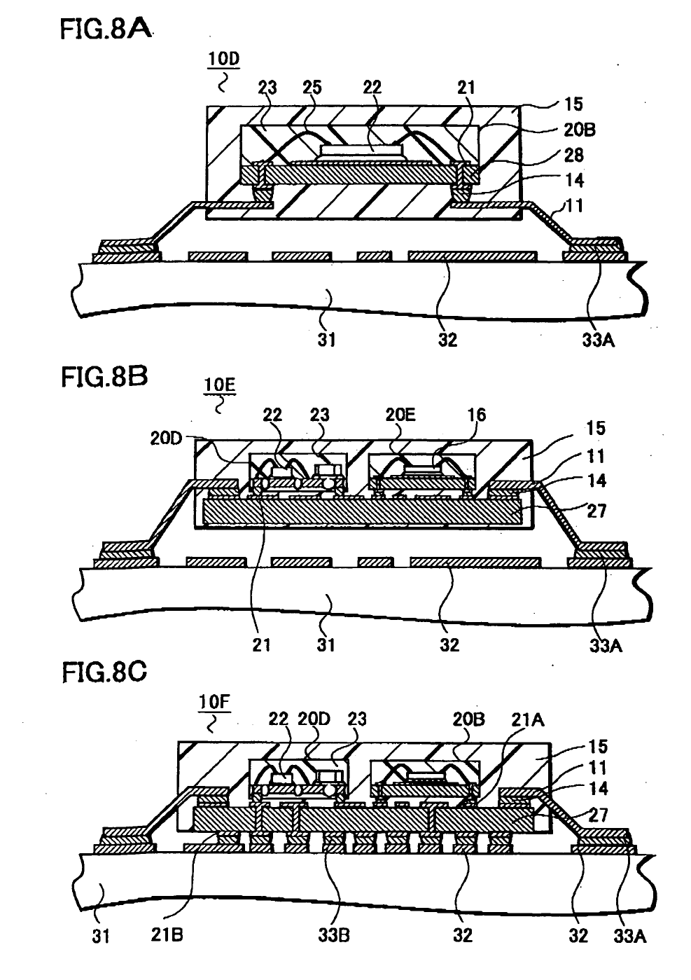

Next, with reference to FIG. 8A to FIG. 8C, a circuit module of other embodiment will be described.

Referring to FIG. 8A, in a circuit module 10D, the circuit device 20B in which the first circuit element 22 is incorporated, is sealed with the second sealing resin 15. Further, the leads 11 electrically connected to the circuit device 20B are led from the second sealing resin 15 to the outside. The leads 11 exposed to the outside are fixed to conductive paths 32 formed on the front surface of a board 31, whereby the mounting of the circuit module 10D is accomplished.

In this example, connection reliability is improved by setting the thermal expansion coefficient of the second sealing resin 15 for sealing the entire circuit module 10D to be larger than that of the first sealing resin 23 partially constituting the circuit device 20B. Specifically, the value of the thermal expansion coefficient of the first sealing resin 23 is adjusted to a small value in consideration of matching with the thermal expansion coefficient of the incorporated element. For example, the thermal expansion coefficient of the first sealing resin 23 is 9×10⁻⁶/° C. to 15×10⁻⁶/° C. On the other hand, in the case where the board 31 is made of glass-epoxy resin, the thermal expansion coefficient thereof is approximately 20×10⁻⁶/° C. Accordingly, the thermal expansion coefficient of the first sealing resin 23 and that of the board 31 greatly differ from each other. Accordingly, supposing that the circuit device 20B is fixed directly to the mount board 21, large tensile and compressive stresses may occur between the two when temperature has changed. In the present embodiment, the thermal expansion coefficient of the entire circuit module 10D is approximated to that of the board 31 by adjusting the thermal expansion coefficient of the second sealing resin 15 to approximately 20×10⁻⁶/° C. to 25×10⁻⁶/° C. This makes it possible to reduce tensile and compressive stresses. Accordingly, the connection reliability of connection portions between the board 31 and the leads 11 can be improved.

The thermal expansion coefficient of the second sealing resin 15 can be adjusted by changing the amount of filler mixed therein. For example, the thermal expansion coefficient of the second sealing resin 15 can be made larger by reducing the mixed amount of filler of SiO₂ or the like having a small thermal expansion coefficient.

Furthermore, in the present embodiment, stress is absorbed by the leads 11. Specifically, one ends of the leads 11 are fixed to the circuit device 20B inside the circuit module 10D. Further, the other ends of the leads 11 which are led to the outside are fixed to conductive paths 32, which are formed on the front surface of the board 31, with connection portions 33A of solder or the like. Moreover, bending is performed on intermediate portions of the leads 11 so that inclined portions are formed. Accordingly, even in the case where the thermal expansion coefficient of the circuit module 10D and that of the board 31 differ from each other, the inclined portions of the leads 11 bend, whereby thermal stress is absorbed.

With reference to FIG. 8B, a circuit module 10E will be described. In this example, the conductive pattern 21 is formed on the front surface of the mount board 27, and circuit devices 20D and 20E are fixed to the conductive pattern 21. Further, the leads 11 are fixed to the conductive pattern 21 placed in the peripheral portion of the mount board 27. In this example, connection reliability is improved by increasing the thermal expansion coefficient of the mount board 27 in accordance with that of the board 31. Specifically, the thermal expansion coefficient of the board 31 is adjusted to approximately 20×10⁻⁶/° C. to 25×10⁻⁶/° C. Moreover, even in the case where a plurality of circuit devices 20 are incorporated in a circuit module as in this case, connection reliability can be further improved by increasing the thermal expansion coefficient of the second sealing resin 15 for sealing the entirety.

In addition, in this example, the second circuit element 16, which is a high-power element, can also be incorporated into the circuit device 20 sealed with resin. Consequently, all incorporated circuit elements can be incorporated therein as packaged products sealed with resin. Accordingly, a mount process can be simplified. It is noted that a power MOSFET, a power transistor, an IGBT, or the like can be adopted as the second circuit element 16. Furthermore, the second circuit element 16 can also be fixed to an island continuous with a lead 11 in a bare-chip state. For example, the second circuit element 16 can be incorporated therein in the state shown in FIG. 1A.

Referring to FIG. 8C, a circuit module 10F will be described. In this example, a plurality of circuit devices 20 are fixed to the front surface of the mount board 27, and the entirety is sealed with the second sealing resin 15. Further, the second conductive pattern 21B formed on the back surface of the mount board 27 is exposed to the outside.

The first conductive pattern 21A is formed on the front surface of the mount board 27, and the second conductive pattern 21B is formed on the back surface thereof. The first and second conductive patterns 21A and second conductive pattern 21B are connected through via holes penetrating the mount board 27. Circuit devices 20 are fixed to the first conductive pattern 21A formed on the front surface. The second conductive pattern 21B formed on the back surface is exposed to the outside to function as external terminals.

The second conductive pattern 21B is exposed to the outside to form external electrodes. The second conductive pattern 21B has a fine pitch of, for example, approximately 0.2 mm, and is formed into the form of a matrix on the back surface of the mount board 27. This structure allows a large number (approximately several hundred) of external terminals to be formed. Moreover, the second conductive pattern 21B is fixed to the conductive paths 32 formed on the front surface of the board 31 with connection portions 33B.

In the circuit module 10F, the leads 11 reduce tensile and compressive stresses, whereby the connection reliability of the connection portions 33B can be ensured. Specifically, compared to the second conductive pattern 21B, the leads 11 are firmly fixed to the board 31. Accordingly, since the leads 11 having high bond strength are located in the peripheral portion, tensile and compressive stresses acting on the connection portions 33B of the second conductive pattern 21B can be reduced. Further, the leads 11 do not necessarily need to function as input/output terminals. Dummy leads 11 may be used. The preferred embodiments of the present invention have the following effects.

The circuit modules of the preferred embodiments each have a lead which function as an external terminal, and a circuit device electrically connected to the lead. Further, the interval of a conductive pattern which the circuit device has is narrower than that between the leads. Accordingly, the circuit modules of the preferred embodiments have large current capacities and favorable heat release properties because of having a lead formed thickly. Furthermore, in the circuit modules of the preferred embodiment, a fine electric circuit can be constituted by the conductive pattern.

In addition, in a circuit module of the preferred embodiment, the thermal expansion coefficient of the second sealing resin for sealing the entirety is larger than that of the first sealing resin partially constituting the incorporated circuit device. Accordingly, the thermal expansion coefficient of the entire circuit module can be approximated to that of a board on which the module is mounted. This makes it possible to reduce thermal stress and to improve the connection reliability of the circuit module.

1. A circuit module comprising:
leads serving as terminals for performing electrical input from, and output to exterior;
a circuit device in which a first circuit element electrically connected to at least one of the leads is sealed with first sealing resin;
a second circuit element fixed to an island formed in one of the leads; and
a second sealing resin for sealing the circuit device and the second circuit element,
wherein the circuit device has a conductive pattern with an interval smaller than that between the leads.

2. The circuit module according to claim 1, wherein the circuit device is electrically connected to the at least one of the leads through a connection portion made of brazing material.

3. The circuit module according to claim 1,
wherein the circuit device is mounted in a state where a surface thereof on which an electrode is exposed is faced up, and
the circuit device is electrically connected to the at least one of the leads through a fine metal wire.

4. The circuit module according to claim 1, wherein at least one of the leads is extended under the circuit device.

5. The circuit module according to claim 1, wherein the conductive pattern has a multilayer wiring structure.

6. The circuit module according to claim 1, wherein the second circuit element is a semiconductor element which generates a larger amount of heat than the fist circuit element.

7. A circuit module comprising:
leads serving as terminals for performing electrical input from, and output to exterior;
a mount board on which a first circuit element electrically connected to at least one of the leads is mounted;
a second circuit element fixed to an island formed in one of the leads; and
sealing resin for sealing the mount board and the first and second circuit elements,
wherein the mount board has a conductive pattern with an interval smaller than that between the leads.

8. The circuit module according to claim 7, wherein the conductive pattern of the mount board is electrically connected to the at least one of the leads through a connection portion made of brazing material.

9. The circuit module according to claim 7, wherein the conductive pattern of the mount board is electrically connected to the at least one of the leads through a fine metal wire.

10. The circuit module according to claim 7, wherein at least one of the leads is extended under the mount board.

11. The circuit module according to claim 7, wherein the mount board is a multilayer board.

12. The circuit module according to claim 7, wherein the second circuit element is a semiconductor element which generates a larger amount of heat than the first circuit element.

13. A circuit module comprising:
a circuit device in which a circuit element is sealed with a first sealing resin;
a second sealing resin for sealing the circuit device; and
leads electrically connected to the circuit device and led from the second sealing resin to exterior,
wherein a thermal expansion coefficient of the second sealing resin is larger than that of the first sealing resin.

14. The circuit module according to claim 13, wherein one ends of the leads are connected to the circuit device inside the second sealing resin, and other ends of the leads are led from the second sealing resin to the outside to be fixed to an external board.

15. The circuit module according to claim 13, further comprising:
a mount board having a conductive pattern formed on a front surface thereof,
wherein the circuit device is electrically connected to the conductive pattern of the mount board, and
the leads are connected to the circuit device through the conductive pattern.

16. The circuit module according to claim 15,
wherein first and second conductive patterns are formed on front and back surfaces of the mount board, respectively,
the first conductive pattern is electrically connected to the circuit device, and
the second conductive pattern is exposed from the second sealing resin to the outside.
